(19) United States
(12) Patent Application Publication
(10) Pub. No.: US 2023/0257307 A1
(43) Pub. Date: Aug. 17, 2023

(54) CERAMIC STRUCTURE AND ELECTROSTATIC DEFLECTOR

(71) Applicant: KYOCERA Corporation, Kyoto-shi, Kyoto (JP)

(72) Inventor: Yuta IMAEDA, Higashiomi-shi, Shiga (JP)

(21) Appl. No.: 18/012,191

(22) PCT Filed: Jun. 28, 2021
(86) PCT No.: PCT/JP2021/024341

§ 371 Date: Dec. 21, 2022

(30) Foreign Application Priority Data
Jun. 30, 2020 (JP) 2020-113321

(51) Int. Cl. C04B 35/478; H01J 37/147; C04B 35/117

(52) U.S. Cl. CPC C04B 35/478; H01J 37/1477; C04B 35/117

(57) ABSTRACT

A ceramic structure includes aluminum oxide as a main component and aluminum titanate, and, in a surface layer region where a depth from a fired surface is within at least 5 mm, at least one of a surface resistance value or a surface resistivity increases in a power approximation or linear approximation manner from the fired surface in a normal direction. An electrostatic deflector includes a cylindrical substrate made of the ceramic structure and a plurality of electrodes provided on an inner peripheral portion of the cylindrical substrate.

### TECHNICAL FIELD

The present disclosure relates to a ceramic structure including aluminum oxide as a main component, and an electrostatic deflector using the ceramic structure.

### BACKGROUND OF INVENTION

In the related art, an electrostatic deflector mounted on an electron beam exposure device or an electron beam irradiation device uses a cylindrical substrate made of ceramics in order to deflect the trajectory of an electron beam. A plurality of polarized electrodes is provided at intervals on an inner peripheral surface of the cylindrical substrate, and a voltage is applied to each of these electrodes to generate a magnetic field, thereby controlling the irradiation direction of the electron beam.

In such a configuration, for example, applying a high voltage in order to increase the resolution of exposure may cause charge-up (electrification) between the electrodes. In order to solve this problem, it is conceivable to widen the distance between the electrodes. However, since increasing the distance between the electrodes increases the size of the electrostatic deflector itself, the electron beam exposure device or the electron beam irradiation device mounted with the electrostatic deflector also increases in size, which results in a problem that it takes time to start up and maintain the device or the cost of the device itself increases.

In order to solve such problems and enable miniaturization, the applicants of the present application have proposed in PTL 1 a specific alumina ceramic as a cylindrical substrate of an electrostatic deflector. That is, this alumina ceramic has the following characteristics: alumina and titanium oxide are main components; a part of the titanium oxide exists as a composite oxide of titanium with alumina including less oxygen than a chemical equivalent; the width between the electrodes is not more than 1 mm; the volume resistivity is 10⁴ to 10¹⁰Ω·m; and the dielectric strength (strength of dielectric breakdown) when voltage is applied under vacuum is not less than 3 kV/mm.

PTL 2 proposes an alumina sintered compact including alumina as a main component and titanium oxide and the like, and the alumina sintered compact has a small variation in a resistance value even though grinding is performed.

### CITATION LIST

### Patent Literature

PTL 1: JP 4313186 B
PTL 2: JP 2007-91488 A

### SUMMARY

In an aspect of the present disclosure, a ceramic structure includes:

aluminum oxide as a main component; and
aluminum titanate.
In a surface layer region where a depth from a fired surface is within at least 5 mm, at least one of a surface resistance value or a surface resistivity increases in a power approximation or linear approximation manner from the fired surface in a normal direction.
In another aspect of the present disclosure, a ceramic structure includes:
aluminum oxide as a main component; and
aluminum titanate.
In a surface layer region where a depth from a fired surface is within at least 5 mm, strength of dielectric breakdown increases from the fired surface in a normal direction.
In another aspect of the present disclosure, an electrostatic deflector includes: a cylindrical substrate made of the ceramic structure; and a plurality of electrodes provided on an inner peripheral portion of the cylindrical substrate.

### BRIEF DESCRIPTION OF THE DRAWINGS

FIG. 1A is a cross-sectional view in a radial direction of an electrostatic deflector according to an embodiment of the present disclosure. FIG. 1B is a cross-sectional view of the electrostatic deflector taken along line X-X′ of FIG. 1A.

FIG. 2 is an optical micrograph illustrating an example of an observation image of a surface layer region S of a ceramic structure according to an embodiment of the present disclosure.

FIG. 3 is a graph showing the relationship between the post-reduction grinding allowance and the surface resistivity in an example and a comparative example of the present disclosure.

FIG. 4 is a graph illustrating the relationship between the post-reduction grinding allowance and the strength of dielectric breakdown in the example and the comparative example of the present disclosure.

### DESCRIPTION OF EMBODIMENTS

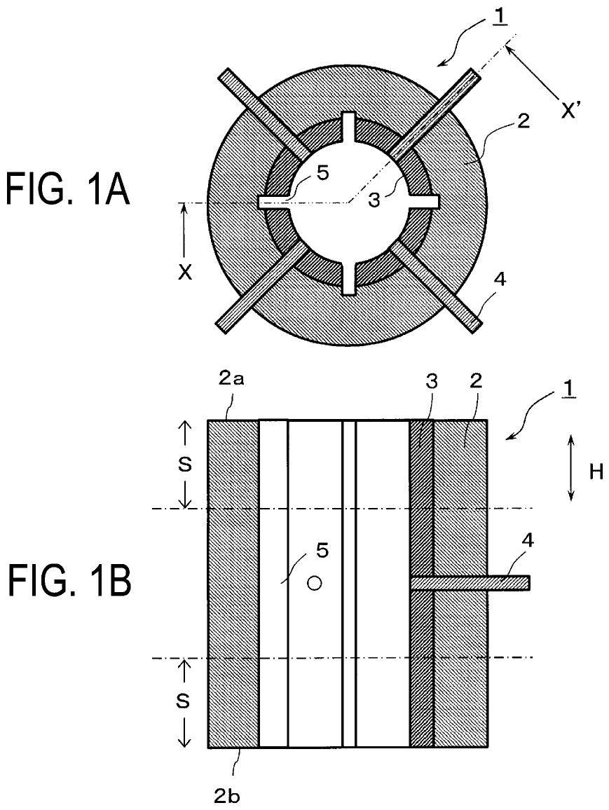

An electrostatic deflector according to an embodiment of the present disclosure is described below with reference to FIGS. 1A and 1B.

An electrostatic deflector 1 of the present embodiment is used as a lens, an aperture member, or a polarizer in an electron optical system, and includes a cylindrical substrate 2, electrodes 3 formed on an inner peripheral portion of the cylindrical substrate 2, and pins 4 for applying a voltage to the electrodes 3 from the outside as connectors for voltage application.

The cylindrical substrate 2 has a cylindrical shape by a through hole formed in the center of a cylinder, and a plurality of the electrodes 3 is formed on the inner peripheral portion via grooves 5 in a circumferential direction. The pins 4 described above are connected to the electrodes 3 by passing through the cylindrical substrate 2 in a radial direction.

The electrode 3 can be any non-magnetic metal film, for example, is made of a metal film of a single metal or a plurality of metals selected from the group consisting of Cu, Ni, Au, Pt, Ag, TiN, and TiC. The plurality of electrodes 3 is formed coaxially with the central axis of the cylindrical substrate 2, and is arranged on the same circumference. The number of electrodes 3 arranged on the same circumference is one or an even number of two or more. When the number of electrodes 3 arranged on the same circumference is an even number of two or more, it is desired that areas of the electrodes 3 exposed on the inner peripheral surface of the cylindrical substrate 2 are approximately the same. When the number of electrodes 3 arranged on the same circumference is an even number of two or more, the electrodes 3 are basically electrically independent electrodes. Note that in FIG. 1A, four electrodes 3 are formed on the same circumference.

The electrodes 3 are polarized with adjacent electrodes 3 by the grooves 5 installed in an axial direction. The groove 5 may have the same length as the thickness of the electrode 3, and may be a groove extending in the thickness direction of the cylindrical substrate 2. Note that in FIG. 1A, the groove 5 is formed up to the cylindrical substrate 2.

In order to achieve the necessary and sufficient performance as the electrostatic deflector 1, the dimensional accuracy of the inner peripheral portion of the cylindrical substrate 2, such as cylindricity, roundness, and coaxiality, needs to have several μm to submicron order. Preferably, the cylindricity and the roundness are not more than 2 μm and the coaxiality of an inner diameter with respect to an outer diameter is not more than 2 μm.

As the material of the pin 4, for example, a non-magnetic material such as Au, Pt, and Cu is used, and the pin 4 is bonded to both the cylindrical substrate 2 and the electrode 3 by brazing and electrically connected to the electrode 3. The brazing portion of the pin 4 may be a non-magnetic brazing material such as Ag, Cu, and Ti, and in order to ensure the airtightness between the inner peripheral portion and the outer peripheral portion of the cylindrical substrate 2, an airtightness of 13.4 μPa or less is required.

The cylindrical substrate 2 is a ceramic structure including aluminum titanate as a main component and aluminum oxide. That is, the ceramic structure can be produced by molding and firing a mixture of aluminum oxide powder and aluminum titanate powder as starting materials, and then performing heat treatment under a reducing atmosphere. In this way, the aluminum titanate powder and the aluminum oxide powder are mixed, molded, and fired, which makes it possible to provide a state in which Al₂TiO₅ is dispersed and dissolved in the grain boundaries of aluminum oxide. Then, a part of the dispersed Al₂TiO₅ is heat-treated in a reducing atmosphere to produce composite oxide (hereinafter, referred to as “oxygen-deficient titanium oxide”) of aluminum oxide and titanium oxide including aluminum oxide as a main component and less oxygen than a chemical equivalent, and such oxygen-deficient titanium oxide is present in the ceramic structure.

The main component in the ceramic structure refers to a component accounting for 75 mass % or more of a total 100 mass % of the components constituting the ceramic structure. The components included in the ceramic structure are identified by an X-ray diffractometer (XRD) using CuKα rays, and the content of the identified components is calculated by a Rietveld method. Trace components not detected by the X-ray diffractometer (XRD) is determined using a fluorescent X-ray analyzer (XRF) or an ICP emission spectrophotometer (ICP).

Oxygen-deficient titanium oxide refers to a state in which titanium oxide forming a solid solution in the grain boundaries of aluminum oxide, for example, a part of Ti⁴⁺ of TiO₂ and Al₂TiO₅ is reduced to Ti³⁺, which can be confirmed by X-ray photoelectron spectroscopy or Auger electron spectroscopy analysis.

This is expressed by a composition formula, for example, TiO₂₋ₓ, (0<x<2) for titanium oxide, and Al₂TiO_{5-y} (0<y<2) for aluminum titanate.

In the above ceramic structure, in a surface layer region where a depth from a fired surface is within at least 5 mm, at least one of a surface resistance value or a surface resistivity increases in a power approximation or linear approximation manner from the fired surface in a normal direction.

The surface resistance value is a resistance value of the surface of the ceramic structure, and is expressed by the following formula:

$$R s = \frac{V}{I} \qquad [ Math . 1 ]$$

where Rs is the surface resistance value (unit: Ω), V is a voltage applied between two electrodes, and I is a current flowing at that time.

The surface resistivity is the surface resistance value per unit surface (1 cm²) of the ceramic structure, and is expressed by the following formula:

$$ρ s = \frac{V}{I} \times \frac{W}{L} \qquad [ Math . 2 ]$$

where ρs is the surface resistivity (unit:Ω/□), W is the width of the electrode, L is the distance between the two electrodes, and V and I are the same as above.

For example, in the case of the cylindrical substrate 2 described above, as illustrated in FIG. 1B, the fired surface refers to at least one end surface 2a or 2b of the cylindrical substrate 2, and the normal direction from the fired surface refers to an axial direction H starting from the end surface 2a or 2b. FIG. 1B schematically illustrates a surface layer region S where a depth from the fired surface, that is, the end surface 2a or 2b is within at least 5 mm.

The fact that the surface resistance value and/or the surface resistivity increases in a power approximation manner means that the amount of change increases as the depth from the fired surface increases.

On the other hand, the fact that the surface resistance value and/or the surface resistivity increase in a linear approximation manner means that the amount of change is substantially constant even though the depth from the fired surface increases.

In this way, the machining depth caused by grinding, polishing, or the like from the fired surface is adjusted by the surface resistance value and/or the surface resistivity increasing in a power approximation or linear approximation manner from the fired surface in the normal direction, which makes it possible to accurately set a surface resistance value and/or a surface resistivity optimal for electrostatic measures that vary depending on the size of the device, the complexity of the shape, or the like.

In the ceramic structure of the present disclosure, it is preferable that the strength of dielectric breakdown increase from the fired surface in the normal direction in the surface layer region S. The increase is in a power approximation or linear approximation manner. Thus, the strength of dielectric breakdown can be set to a desired value while taking into consideration the machining costs caused by grinding or polishing the fired surface.

The strength of dielectric breakdown in the fired surface is not less than 6 kV/mm, preferably not less than 8 kV/mm. Thus, problems due to dielectric breakdown can be eliminated. The strength of dielectric breakdown can be measured by a method conforming to JIS C2110:1992.

However, when the ceramic structure is small and a test piece defined by JIS C2110:1992 is not cut out from the ceramic structure, the test piece is adjusted to have a maximum size.

Whether the surface resistance value and/or the surface resistivity, or the strength of dielectric breakdown increases in a power approximation or linear approximation manner from the fired surface in the normal direction is determined at a significance level of 5%, preferably at a significance level of 1%. When the output indicates that it is not significant at the significance level of 5%, it is difficult to set an optimal surface resistance value and/or surface resistivity, or strength of dielectric breakdown by adjusting the machining depth caused by grinding, polishing, or the like from the fired surface.

Preferably, the ceramic structure of the present disclosure includes, at least in the fired surface, magnesium aluminate MgAl₂O₄ in addition to aluminum oxide Al₂O₃ and aluminum titanate Al₂TiO_{5-y} (0<y<2). The content of the magnesium aluminate in the fired surface is not more than 5 mass %, preferably not more than 4.5 mass %, relative to the total amount. Note that the magnesium aluminate may be present in the entire surface region S including the fired surface. The content of the magnesium aluminate in a grinding surface at a desired depth in the surface layer region S is 5 mass %, preferably 4.5 mass %, relative to the total amount.

The content of the magnesium aluminate in the surface layer region S is calculated by the Rietveld method using the X-ray diffractometer, with the fired surface and the grinding surface at a desired depth in the surface layer region S as measurement targets.
Since the magnesium aluminate has a high corrosion resistance to alkaline solutions, the ceramic structure including the magnesium aluminate in at least the fired surface can reduce erosion of the fired surface even when being washed with an alkaline solution. Such magnesium aluminate is derived from magnesium hydroxide added as a sintering aid, as will be described below.

The magnesium aluminate on the fired surface preferably includes titanium forming a solid solution. This makes it possible to make creeping dielectric breakdown of the ceramic structure less likely to occur. Such titanium is considered to be derived from aluminum titanate included in a mixed powder of raw materials, as will be described below.

On the other hand, preferably, at least the surface layer region S of the ceramic structure includes no titanium oxide. Otherwise, when the ceramic structure is continuously used at a high temperature, the titanium oxide reacts with aluminum oxide to newly produce aluminum titanate, which destabilizes the characteristics of the surface layer region S. A region other than the surface layer region S may include the titanium oxide, but preferably includes no titanium oxide in order to stabilize the characteristics of the ceramic structure. The content of aluminum titanate in the fired surface is from 10 mass % to 20 mass %, preferably from 12 mass % to and 18 mass %, relative to the total amount. The content of aluminum titanate in the grinding surface at the desired depth in the surface layer region S is also from 10 mass % to 20 mass %, preferably from 12 mass % to 18 mass %, relative to the total amount.

The content of each of titanium oxide and aluminum titanate in the surface layer region S may be calculated by the Rietveld method using the X-ray diffractometer, with the fired surface and the grinding surface at the desired depth in the surface layer region S as measurement targets.

The surface layer region S includes closed pores, and a difference A between an average value of inter-centroid distances of the closed pores adjacent to each other and an average value of equivalent circle diameters of the closed pores is not less than twice and not more than four times a difference B between an average value of inter-centroid distances of adjacent crystal grains of aluminum titanate and an average value of equivalent circle diameters of crystal grains of aluminum titanate.

The difference A between the average value of the inter-centroid distances of the closed pores adjacent to each other and the average value of the equivalent circle diameters of the closed pores is an average value of intervals between the closed pores adjacent to each other. The difference B between the average value of the inter-centroid distances of the adjacent crystal grains of aluminum titanate and the average value of the equivalent circle diameters of the crystal grains of aluminum titanate is an average value of intervals between the adjacent crystal grains of aluminum titanate.

Aluminum titanate tends to include microcracks, and once microcracks are present, accumulated residual stress is relaxed by the microcracks when the ceramic structure is used in a high-temperature environment, so cracks are less likely to evolve. Some crystal grains of aluminum titanate include no microcracks, and in this case, closed pores located in the vicinity of the crystal grains of aluminum titanate relax residual stress, so cracks are less likely to evolve. When the difference A is equal to or less than 4 times the difference B, the effect is remarkable. On the other hand, when the interval between the closed pores decreases, mechanical strength may decrease, and thus the difference A is not less than twice the difference B in order to maintain the mechanical strength. The equivalent circle diameters of closed pores are calculated by the following method.

First, the cross-section of the surface layer region is polished until a mirror surface is made. Specifically, the following first polishing to third polishing are performed sequentially.
(1) First polishing: polishing by a diamond disk using diamond abrasive grains having an average grain size D₅₀ of 45 μm
(2) Second polishing: Polishing with a copper plate using diamond abrasive grains having an average grain size D₅₀ of 3 μm
(3) Third polishing: Polishing with a tin plate using diamond abrasive grains having an average grain size D₅₀ of 0.5 μm

An average range is selected from a polished surface processed by the above polishing, and an observation image is obtained by photographing a range having an area of, for example, 1.06×10⁵ μm² (376 μm in transverse length and 282 μm in longitudinal length) with an optical microscope.

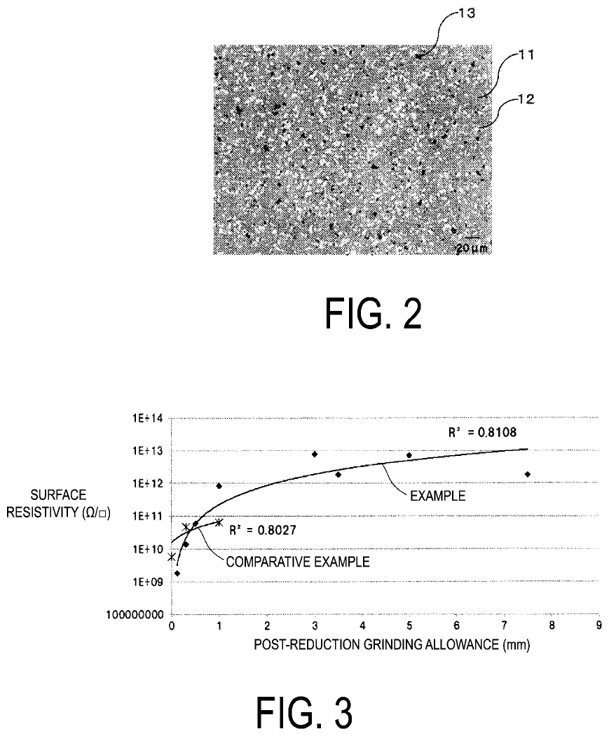

FIG. 2 illustrates an example of an observation image of the surface layer region S of the ceramic structure of the present disclosure.

The observation image includes crystal grains (gray portions) 11 of aluminum oxide as a main component, crystal grains (white portions) 12 of aluminum titanate, and closed pores (black portions) 13.

The crystal grains (white portion) 12 of aluminum titanate can be confirmed by using both the X-ray diffractometer (XRD) using CuKα rays and an energy dispersive X-ray spectrometer (EDS). Specifically, the X-ray diffractometer (XRD) using CuKα rays is used to identify aluminum titanate included in the ceramic structure. When the energy dispersive X-ray spectrometer is used to irradiate the white portions 12 with an electron beam and Al, Ti, and O are detected, the white portions 12 may be regarded as the crystal grains of aluminum titanate.

The equivalent circle diameters of the closed pores 3 are calculated for the observation image by a method called particle analysis using image analysis software “Azo-kun (ver. 2.52)” (trade name, manufactured by Asahi Kasei Engineering Corporation), and then, the average value of the equivalent circle diameters is calculated. Hereinafter, the term image analysis software “Azo-kun” refers to the image analysis software manufactured by Asahi Kasei Engineering Corporation throughout the description.

As setting conditions of this method, for example, a threshold value, which is an indicator indicating the contrast of an image, is set to 140, brightness is set to dark, and a small figure removal area is set to 0.5 μm², and a noise removal filter is set to presence. When the observation image illustrated in FIG. 2 is targeted under these setting conditions, the average value of the equivalent circle diameters of the closed pores 13 is 3.5 μm.
The threshold value is adjusted according to the brightness of the observation image. Specifically, after the brightness is set to dark, a binarization method is set to manual, the small figure removal area is set to 0.5 μm², and the noise removal filter is set to presence, the threshold value is adjusted in such a manner that a marker appearing in the observation image matches the shape of the closed pores 13.

The inter-centroid distances of the closed pores 13 can be calculated by the following method.

In order to calculate the equivalent circle diameters of the closed pores 13, the inter-centroid distances of the closed pores 13 are calculated for the photographed observation image by a method called an inter-centroid distance method for dispersivity measurement by using the image analysis software “Azo-kun (ver. 2.52)”, and then, the average value of the inter-centroid distances is calculated.
The setting conditions for this method are the same as the setting conditions for calculating the equivalent circle diameters of the closed pores 3.
When the observation image illustrated in FIG. 2 is targeted under these setting conditions, the average value of the inter-centroid distances of the closed pores 13 is 24.1 μm. Accordingly, the difference A is 20.6 μm.

The equivalent circle diameters of the crystal grains 12 of aluminum titanate are calculated for the observation image by a method called particle analysis using the image analysis software “Azo-kun”, and then, the average value of the equivalent circle diameters is calculated. As setting conditions of this method, for example, the threshold value, which is an indicator indicating the contrast of an image, is set to 200, the brightness is set to bright, the small figure removal area is set to 0.5 μm², and the noise removal filter is set to present. When the observation image illustrated in FIG. 2 is targeted under these setting conditions, the average value of the equivalent circle diameters of the crystal grains 2 of aluminum titanate is 4.4 μm. The threshold value is adjusted according to the brightness of the observation image.

Specifically, after the brightness is set to dark, the binarization method is set to manual, the small figure removal area is set to 0.5 μm², and the noise removal filter is set to be present, the threshold value is adjusted in such a manner that a marker appearing in the observation image matches the shape of the crystal grains 12 of aluminum titanate.

The inter-centroid distances of the crystal grains 12 of aluminum titanate can be calculated by the following method.

The inter-centroid distances of the crystal grains 12 of aluminum titanate are calculated for the observation image by a method called the inter-centroid distance method for dispersivity measurement by using the image analysis software “Azo-kun (ver. 2.52)”, and then, the average value of the inter-centroid distances is calculated.
The setting conditions of this method are the same as the setting condition for calculating the equivalent circle diameters of the crystal grains 12 of aluminum titanate.
When the observation image illustrated in FIG. 2 is targeted under these setting conditions, the average value of the inter-centroid distances of the crystal grains 12 of aluminum titanate is 12.3 μm.
Accordingly, the difference B is 7.9 μm, and the difference A is 2.6 times the difference B.
The area ratio of the closed pores 13 in the surface layer region S is, for example, not more than 4%, and the surface layer region S are dense.
The area ratio of the closed pores 13 is calculated by the method called particle analysis. The average value of the equivalent circle diameters of the crystal grains 11 of aluminum oxide and the crystal grains 12 of aluminum titanate in the surface layer region S may be from 0.5 μm to 7 μm.
Once the average value of the equivalent circle diameters of the crystal grains 11 and 12 of the above components is not less than 0.5 μm, an area occupied by a grain boundary phase having low corrosion resistance to plasma is relatively reduced when used in a plasma space, and thus the corrosion resistance to plasma is improved. When the average value of the equivalent circle diameters of the crystal grains of the above components is not more than 7 μm, mechanical properties such as mechanical strength and rigidity are improved.

The coefficient of variation in the equivalent circle diameters of the crystal grains of aluminum oxide and aluminum titanate in the surface layer region S may be from 0.5 to 0.8. When the coefficient of variation in the equivalent circle diameters of the crystal grains 11 and 12 is from 0.5 to 0.8, large crystal grains and small crystal grains are appropriately mixed, and thus the fracture toughness increases.

The kurtosis of the equivalent circle diameters of the crystal grains of aluminum oxide and aluminum titanate in the surface layer region S may be from 3 to 5.
The kurtosis Ku is an indicator (statistic) indicating how different the peak and tail of the distribution are from those of the normal distribution. When kurtosis Ku>0, the distribution has a sharp peak and a long and thick tail. When kurtosis Ku=0, the distribution becomes the normal distribution. When kurtosis Ku<0, the distribution has a rounded peak and a short and thin tail. Note that the kurtosis Ku of the equivalent circle diameters of the crystal grains of the above components is calculated using the function KURT provided in Excel (trade name, available from Microsoft Corporation).
When the kurtosis of the equivalent circle diameters of the crystal grains 11 and 12 of the above components is within the above range, the distribution of the equivalent circle diameters of the crystal grains is narrow and the number of crystal grains with an abnormally large equivalent circle diameter is small, and thus cracks are less likely to occur even when the ceramic structure is used in an environment where heating and cooling are repeated, and thus long-term use is possible.

The equivalent circle diameters of the crystal grains 11 and 12 are determined by photographing a surface, which is obtained by heat-treating the polished surface processed by the above-described method at 1350° C., by using a digital macroscope (VHX-500) at a magnification of 400 times. Specifically, a range having an area of 7.2×10⁻³ mm² in the photographed image is set as a measurement range. By analyzing the above measurement range by using image analysis software (for example, Win ROOF manufactured by Mitani Corporation), the equivalent circle diameters of the crystal grains 11 and 12 can be calculated.

In the analysis, when a threshold value of grain sizes is set to 0.2 μm, the grain sizes of 0.2 μm or less are not subject to the calculation of the equivalent circle diameter, the coefficient of variation, and the kurtosis.

Next, an example of a method of manufacturing the ceramic structure of the present disclosure is described.

First, a powder (hereinafter, referred to as a mixed powder) is prepared by mixing a powder of aluminum oxide having a purity of 99 mass % or more and an average grain size of 0.4 μm to 0.8 μm, a powder of aluminum titanate having a purity of 99 mass % or more and an average grain size of 0.3 μm to 20 μm, a powder of magnesium hydroxide, and a powder of silicon dioxide as a sintering aid. The prepared mixed powder is wet-mixed and pulverized, and is subjected to addition of a molding aid such as polyethylene glycol or acrylic resin to form a slurry. Particularly, an average grain size of the powder of aluminum titanate is preferably 3 μm to 15 μm. The slurry is dried by a spray dryer and granulated to produce a secondary raw material.

It is assumed that in 100 mass % of the mixed powder, the powder of aluminum titanate is 20 mass % to 22 mass %, the powder of the magnesium hydroxide is 0.1 mass % to 0.3 mass %, and the powder of the silicon dioxide is 0.3 mass % to 0.9 mass %, and the balance is the powder of aluminum oxide.

The produced secondary raw material is molded into a desired shape by applying a molding pressure in a range of 70 to 200 MPa by a known molding method such as cold isostatic pressing (CIP) molding or mechanical press molding, and the molded product is cut into a desired shape.

Subsequently, the cut product is fired in such a manner that the maximum temperature is in the range of 1400 to 1600° C. to produce a sintered compact. Subsequently, each fired surface of the sintered compact is ground or polished to remove a portion of, for example, 0.01 mm to 0.2 mm from the fired surface in a depth direction.

Subsequently, by heat-treating the sintered compact at a temperature of 1000° C. to 1500° C. in a reducing atmosphere of forming gas (mixed gas of hydrogen and nitrogen), the ceramic structure of the present disclosure can be produced. The volume ratio of hydrogen and nitrogen in the forming gas is preferably hydrogen/nitrogen=10/90 to 30/70.

When the volume ratio of hydrogen and nitrogen is the above ratio, at least one of the surface resistance value and the surface resistivity increases in a power approximation or linear approximation manner from the fired surface in a normal direction in the surface layer region S from the fired surface of the ceramic structure.

### EXAMPLES

The ceramic structure of the present disclosure is described in detail below using an example, but the present disclosure is not limited to the following example.

78.2 mass % of an aluminum oxide powder having a purity of 99.5 mass % and an average grain size of 0.5 μm, 21 mass % of an aluminum titanate powder having a purity of 99.7% and an average grain size of 6.5 μm, 0.2 mass % of a magnesium hydroxide powder, and 0.6 mass % of a silicon dioxide powder were weighted, were subjected to addition of balls made of zirconium oxide having a purity of 99.9 mass % and ion-exchanged water, and were wet-mixed and pulverized until the pulverized grain size is 0.3 μm. Subsequently, a molding aid was added to the pulverized powder to form a slurry. The slurry was dried using a spray dryer to produce granules. After sizing the granules through an 80 mesh, the sized powder was filled into a molding space and mechanically press-molded at a pressure of 98 MPa. After firing the produced powder compact at a maximum temperature of 1500° C., the fired surface of the sintered compact was ground to remove a portion of 0.1 mm from the fired surface in the depth direction.

Subsequently, the sintered compact was heat-treated at 1350° C. in a reducing atmosphere with forming gas (mixed gas of hydrogen/nitrogen=13/87 in volume ratio) to produce a disk-shaped ceramic structure having a diameter of 50 mm and a thickness of 2 mm.

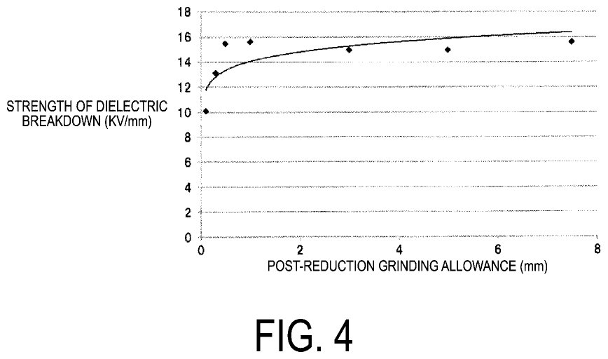

The fired surface (principal surface) of the produced disk-shaped ceramic structure was ground in the normal direction (thickness direction), and the surface resistivity and the strength of dielectric breakdown were measured for each predetermined depth (grinding allowance). The results are illustrated in FIGS. 3 and 4. In FIGS. 3 and 4, a power approximation curve is determined from the plotted measured values.

As illustrated in FIG. 3, in the ceramic structure produced in the example, the surface resistivity increases in a power approximation manner in the normal direction. As illustrated in FIG. 4, in the ceramic structure produced in the example, the strength of dielectric breakdown increases in the normal direction.

The composition and content of each component were measured for each depth from the fired surface of the produced ceramic structure. The results are shown in Table 1. The composition of the components shown in Table 1 is a composition identified by the X-ray diffractometer (XRD) using CuKα rays. The contents of the identified components are values calculated by the Rietveld method.

TABLE 1

| | Depth from fired surface (mm) | | | | | | | | |
|---|---|---|---|---|---|---|---|---|---|
| | 0 mm | 0.1 mm | 0.3 mm | 0.5 mm | 1.0 mm | 3.0 mm | 5.0 mm | 7.5 mm | 15.0 mm |
| Al₂O₃ | 84.7 | 81.1 | 81.2 | 81.2 | 81.1 | 81.4 | 81.1 | 81.3 | 81.1 |
| Al₂TiO₅ | 14.2 | 14.6 | 14.7 | 14.9 | 15.0 | 14.9 | 15.1 | 15.0 | 15.0 |
| MgAl₂O₄ | 1.1 | 4.3 | 4.0 | 3.9 | 3.9 | 3.8 | 3.9 | 3.7 | 3.8 |
| TiO₂ | 0 | 0 | 0 | 0 | 0 | 0 | 0 | 0 | 0 |

(Unit: mass %)

### COMPARATIVE EXAMPLE

PTL 2 (JP 2007-91488 A) discloses an alumina sintered compact including aluminum oxide as a main component and aluminum titanate, and the comparative example discloses that the surface resistance increases as it advances inside by grinding. The comparative example of PTL 2 is as follows.

Al₂O₃ and TiO₂ are used as raw material powders, are mixed in a composition ratio of 2.5 mass % of TiO₂ and the balance of Al₂O₃, an organic solvent such as alcohol is added to the mixed powder, the mixed powder is wet-mixed and pulverized in a ball mill to produce a granulated powder by a spray dryer, the produced granulated powder is molded into a powder compact by a mechanical press at a pressure of 98 MPa and is fired at 1350° C. in a reducing atmosphere including nitrogen and hydrogen to complete an evaluation piece.

The produced evaluation piece is ground by 0, 300, 1000 μm from the surface, and the surface resistivity in the depth direction is measured each time. The measurement results shown in Table 1 (paragraph 0026) of PTL 2 are illustrated in FIG. 3 as a comparative example.

In FIG. 3, a change in the surface resistivity is shown by a power approximation curve in the example and by a linear approximation curve in the comparative example. Table 2 below shows the results of testing the degree of conformity at the significance levels of 5% and 1%. In the comparative example, both linear approximation and power approximation are conceivable, and thus the degree of conformity of both approximation curves was examined in the same and/or similar way.

TABLE 2

| | Approximation | Number of | | | Significance | Significance |
|---|---|---|---|---|---|---|
| SAMPLE | curve | samples | R² | R | level of 5% | level of 1% |
| Example | Power | 8 | 0.8108 | 0.9004 | Significant | Significant |
| | approximation | | | | | |
| Comparative | Linear | 3 | 0.8027 | 0.8959 | Not significant | Not significant |
| example | approximation | | | | | |
| | Power | 3 | Not | Not | Not significant | Not significant |
| | approximation | | calculable | calculable | | |

From Table 2, it was found that in the comparative example, as a result of testing the value of the surface resistivity for each grinding allowance at a significance level of 5% with respect to both power approximation and linear approximation, a correlation coefficient R and a determination coefficient R² are not calculable in the power approximation and are calculated but not significant in the linear approximation.

On the other hand, in the example, it was found that the power approximation curve is significant at a significance level of 5% and a significance level of 1%, respectively. From these results, it can be seen that the ceramic structure of the present disclosure can accurately set the surface resistance value and/or the surface resistivity optimal for electrostatic measures by adjusting the machining depth caused by grinding, polishing, or the like from the fired surface.
In the ceramic structure of the example, it was also found that the power approximation curve of the strength of dielectric breakdown illustrated in FIG. 4 is also significant at a significance level of 5% and a significance level of 1%, respectively.

Although an embodiment of the ceramic structure of the present disclosure has been described above, the present disclosure is not limited to the above embodiment and various changes and improvements can be made within the scope of the present disclosure. For example, it goes without saying that the ceramic structure of the present disclosure can be applied to various applications necessary for electrostatic measures, in addition to being used as the cylindrical substrate of the electrostatic deflector described above.

### REFERENCE SIGNS

1 Electrostatic deflector
2 Cylindrical substrate
2a, 2b End surface (fired surface)
3 Electrode
4 Pin
5 Groove
11 Crystal grains (gray portions) of aluminum oxide
12 Crystal grains (white portions) of aluminum titanate
13 Closed pores (black portions)
H Axial direction (normal direction)
S Surface layer region

1. A ceramic structure comprising:
aluminum oxide as a main component; and
aluminum titanate,
wherein, in a surface layer region where a depth from a fired surface is 5 mm or less, at least one of a surface resistance value or a surface resistivity increases in a power approximation or linear approximation manner from the fired surface in a normal direction.

2. A ceramic structure comprising:
aluminum oxide as a main component; and
aluminum titanate,
wherein, in a surface layer region where a depth from a fired surface is 5 mm or less, strength of dielectric breakdown increases from the fired surface in a normal direction.

3. The ceramic structure according to claim 1, wherein at least the fired surface comprises magnesium aluminate.

4. The ceramic structure according to claim 3, wherein the magnesium aluminate on the fired surface comprises titanium forming a solid solution.

5. The ceramic structure according to claim 1, wherein at least the surface layer region comprises no titanium oxide.

6. The ceramic structure according to claim 1, wherein the surface layer region comprises closed pores, and a difference A between an average value of inter-centroid distances of the closed pores adjacent to each other and an average value of equivalent circle diameters of the closed pores is two to four times a difference B between an average value of inter-centroid distances of adjacent crystal grains of aluminum titanate and an average value of equivalent circle diameters of crystal grains of aluminum titanate.

7. The ceramic structure according to claim 1, wherein an average value of equivalent circle diameters of crystal grains of aluminum oxide and aluminum titanate in the surface layer region is from 0.5 μm to 7 μm.

8. The ceramic structure according to claim 1, wherein a coefficient of variation in the equivalent circle diameters of crystal grains of aluminum oxide and aluminum titanate in the surface layer region is each from 0.5 to 0.8.

9. The ceramic structure according to claim 1, wherein a kurtosis Ku of the equivalent diameters of crystal grains of aluminum oxide and aluminum titanate in the surface layer region is from 3 to 5.

10. An electrostatic deflector comprising:
a cylindrical substrate made of the ceramic structure according to claim 1; and
a plurality of electrodes provided on an inner peripheral portion of the cylindrical substrate.

11. The electrostatic deflector according to claim 10, wherein, in the ceramic structure, the fired surface is ground or polished to a predetermined depth within a range of the surface layer region in such a manner that at least one of the surface resistance value or the surface resistivity has a desired value.

12. The electrostatic deflector according to claim 10, wherein, in the ceramic structure, the fired surface is ground or polished to a predetermined depth within a range of the surface layer region in such a manner that the strength of dielectric breakdown has a desired value.
